(19) United States
(12) Patent Application Publication
(10) Pub. No.: US 2024/0213158 A1
(43) Pub. Date: Jun. 27, 2024

(54) LOW RESISTANCE BOTTOM ELECTRODE VIA

(71) Applicant: Taiwan Semiconductor Manufacturing Company, Hsinchu (TW)

(72) Inventor: Chia-Hua Lin, New Taipei (TW)

(21) Appl. No.: 18/093,472

(22) Filed: Jan. 5, 2023

Related U.S. Application Data
(60) Provisional application No. 63/435,467, filed on Dec. 27, 2022.

(51) Int. Cl. H01L 23/532; H01L 21/768; H01L 23/522; H10B 61/00

(52) U.S. Cl. CPC H01L 23/53266; H01L 21/76802; H01L 21/7684; H01L 21/76846; H01L 21/76877; H01L 23/5226; H10B 61/00

(57) ABSTRACT

An integrated circuit fabrication method comprises: providing a semiconductor wafer including a dielectric layer disposed over a copper or copper alloy layer; forming a via opening in the dielectric layer exposing a portion of the copper or copper alloy layer; disposing a copper-barrier layer in the via opening; disposing an oxophilic layer on the copper-barrier layer wherein the semiconductor wafer is not exposed to air between an end of the disposing of the copper-barrier layer and a start of the disposing of the oxophilic layer; after disposing the oxophilic layer, filling the via opening with tungsten to form a tungsten via; and forming an electronic device in electrical contact with the copper or copper alloy layer by way of the tungsten via.

This application claims the benefit of U.S. Provisional Application No. 63/435,467 filed Dec. 27, 2022 and titled “LOW RESISTANCE BOTTOM ELECTRODE VIA”, which is incorporated herein by reference in its entirety.

### BACKGROUND

The following relates to the integrated circuit (IC) arts, bottom electrical via (BEVA) fabrication arts, nonvolatile memory fabrication arts, magnetoresistive random access memory (MRAM) arts, and related arts.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 diagrammatically illustrates a cross-sectional view of a magnetoresistive random access memory (MRAM).

FIG. 2 diagrammatically illustrates a fabrication process for fabricating a bottom electrode via (BEVA) for connecting with an MRAM or other device that includes air exposure after formation of the copper-barrier.

FIG. 3 diagrammatically illustrates a first fabrication process for fabricating a BEVA for connecting with an MRAM or other device.

FIG. 4 presents a flow chart for the first fabrication process for fabricating a BEVA.

FIG. 5 presents experimental results measured for test structures as diagrammatically indicated by cross-sectional views in the lower portion of FIG. 5.

FIG. 6 diagrammatically illustrates a second fabrication process for fabricating a BEVA for connecting with an MRAM or other device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Integrated circuit (IC) designs that utilize multi-layer architectures include electrical vias to connect devices between different layers. A common type of via is a bottom electrode via (BEVA) that connects a lower copper or copper alloy layer with a device formed above the copper or copper alloy layer. As an example, the IC design may include multiple metallization layers with intervening intermetal dielectric (IMD) layers, and a BEVA extends from the metallization layer (which in this example is the copper or copper alloy layer) and the bottom electrode of an electronic device. As a more specific example, an array of magnetoresistive random access memory (MRAM) devices or other nonvolatile memory devices may be provided, with bottom electrodes that are connected to underlying copper traces of a patterned copper or copper alloy layer. In such an IC, it can be desirable to closely pack the MRAM devices to achieve an MRAM array with a high device packing density to provide a compact memory. High device packing density corresponds to a reduced maximum critical dimension (CD) in the lateral direction for the BEVA structures that connect with the MRAM array. Furthermore, reducing the BEVA CD facilitates corresponding reduction in the critical dimension of the magnetic tunnel junction (MTJ) of the MRAM, which results in less power consumption and faster write time for the MRAM.

However, reducing the CD of the BEVA has the effect of increasing the electrical resistance introduced by the BEVA. In general, the resistance R of a via having cross-sectional area A and height H is given by

$$R = \frac{ρ H}{A}$$

where ρ is the electrical resistivity of the via material. For a via of circular cross-section, its area is

$$A = π {r}^{2} = \frac{π}{4} {d}^{2}$$

where r is the via radius and d is the via diameter. Hence, the resistance of the BEVA for a given height H and given material decreases rapidly with decreasing critical dimension CD (corresponding to the decreasing diameter d in this example).

In some compact MRAM designs, it is desired for the BEVA to have a maximum lateral dimension at its contact with the underlying copper or copper alloy layer (hereinafter referred to as the bottom CD of the BEVA) of 50 nm or less, and a ratio of via height to bottom CD equal to 1.6 or larger. A typical material for the BEVA underlying an MRAM is titanium nitride (TiN). However, it was found experimentally in attempting to fabricate a BEVA with a bottom CD of 45 nm made of TiN, attempting to fill the via opening with TiN to form the BEVA resulted in incomplete filling leaving a central void, and hence a defective BEVA. For a larger bottom CD of 65 nm the TiN was able to fill the via opening, but the relatively high resistivity of TiN (resistivity ρ of 300 μΩ·cm or greater) resulted in the BEVA exhibiting a high contact resistance (R_{c,BEVA}) of about 200Ω. As noted above, this high value of R_{c,BEVA} is problematic, since it reduces the tunnel magnetoresistance ratio (TMR) of the MRAM. The TMR quantifies the difference between the high resistance state and the low resistance state of the MRAM—hence, a reduction in TMR narrows the read window of the MRAM. Consequently, a high BEVA contact resistance R_{c,BEVA} reduces the TMR of the MRAM and makes it more difficult to distinguish between the high resistance versus low resistance states during MRAM readout.

It might be expected that substituting a lower resistance metal, such as tungsten (W) which has a resistivity of 30 μΩ·cm or less (i.e. about a tenfold decrease compared with TiN), would significantly improve (i.e. reduce) the BEVA contact resistance R_{c,BEVA}. However, it was found in experiments that substituting tungsten for TiN in BEVA designs resulted in BEVA contact resistances R_{c,BEVA} that were not reduced as much as would be expected given the large reduction in resistivity when compared with TiN BEVA structures of comparable dimensions.

In some embodiments disclosed herein, BEVA designs and corresponding fabrication methods are disclosed which overcome these difficulties and others. In some disclosed embodiments, tungsten is used as the fill material for the BEVA, which was found experimentally to provide complete filling of the via opening without formation of a central void even for BEVA bottom CD of as low as 45 nm. (By comparison, as noted earlier attempting to use TiN to fill a via opening with a 45 nm bottom CD was unsuccessful as it resulted in a central void). Additionally, it was found that to achieve the lowest BEVA contact resistance R_{c,BEVA}, measures should be taken to avoid oxidation of the copper-barrier of the BEVA. In some embodiments, this is achieved by disposing an oxophilic layer on the copper-barrier layer (which may, for example, include a tantalum layer, a tantalum nitride layer, a molybdenum layer, a molybdenum nitride layer, a cobalt layer, a cobalt nitride layer, or a combination of two or more thereof) by using a fabrication sequence in which the semiconductor wafer is not exposed to air between an end of the disposing of the copper-barrier layer and the start of the disposing of the oxophilic layer. In some embodiments, the semiconductor wafer is not exposed to air during a time interval encompassing the deposition of the copper-barrier layer and the deposition of at least an initial portion of the oxophilic layer. The oxophilic layer may, for example, include a titanium layer, a titanium nitride (TiN) layer, or a combination thereof (e.g., a Ti/TiN bi-layer).

Without being limited to any particular theory of operation, it is believed that the less-than-expected reduction in BEVA contact resistance R_{c,BEVA} obtained by substituting tungsten fill material for the TiN fill material is due to formation of high resistance oxide layer on the copper-barrier layer due to air exposure during transfer of the semiconductor wafer from the tool used to deposit the copper-barrier to the tool used to deposit the tungsten glue layer that is applied prior to filling the via opening with tungsten. While this was experimentally observed for a copper-barrier that includes a tantalum nitride/tantalum (TaN/Ta) bilayer, similar oxidation may occur during air exposure of a copper-barrier comprising only TaN, or only Ta, or comprising molybdenum, cobalt, and/or nitrides thereof in some embodiments. This high resistance oxide film or layer partially or wholly overrides the reduction in resistance achieved by the tungsten, resulting in the less-than-expected reduction in BEVA contact resistance.

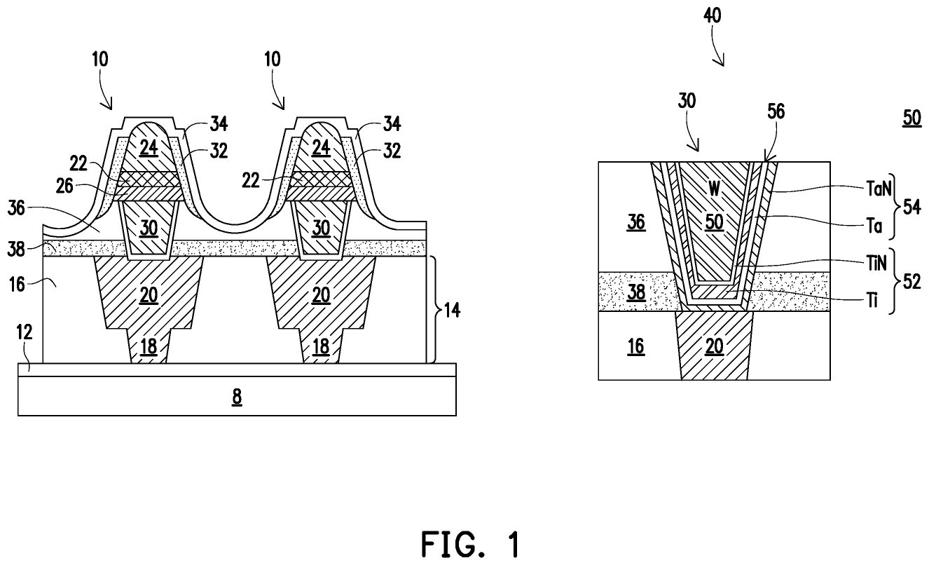

With reference to FIG. 1, a semiconductor wafer 8 with two illustrative MRAM devices 10 formed thereon (for example, two MRAM cells 10 of an MRAM array) is shown by diagrammatic cross-sectional view. The semiconductor wafer 8 may have various semiconductor devices fabricated thereon and/or therein, such as metal-oxide-semiconductor field-effect transistors (MOSFETs) or the like, as diagrammatically indicated in FIG. 1 by a semiconductor devices layer 12 (which in various embodiments may itself comprise two or more semiconductor device layers). The MRAMs 10 are formed at a layer located above the semiconductor devices layer 12, and one or more metallization layers (illustrative single metallization layer 14) are interposed between the semiconductor layer 12 and the MRAMs 10. Each metallization layer 14 typically includes an intermetal dielectric (IMD) layer 16 with electrical vias 18 passing therethrough, and a copper or copper alloy layer 20 which is typically patterned to define electrical traces. The IMD 16 may, for example, comprise silicon oxide, fluorinated silica glass (FSG), carbon doped silicon oxide, tetra-ethyl-ortho-silicate (TEOS) formed oxide, phosphosilicate glass (PSG), or borophosphosilicate glass (BPSG), as some nonlimiting illustrative examples.

Each MRAM 10 includes a magnetic tunnel junction (MTJ) 22, whose design is chosen for the particular characteristics desired for the MRAM 10. By way of nonlimiting illustrative example, the MTJ 22 can be formed as a stack including: a seed layer (e.g., Ta, TaN, Cr, Ti, TiN, Pt, Mg, Mo, Co, Ni, Mn, or alloys thereof); a ferromagnetic layer (e.g., Co, Fe, Ni, B, Mo, Mg, Ru, Mn, Ir, Pt, or alloys thereof); a tunneling layer (e.g., MgO, Al₂O₃, AlN, AlON, HfO₂, ZrO₂, or combinations thereof), optionally another ferromagnetic layer, and a capping layer (e.g., Ta, Co, B, Ru, Mo, MgO, AlO, or combinations thereof). It is to be understood these are merely nonlimiting illustrative examples. Each MRAM 10 further includes a top electrode 24, for example made of Ti, Ta, Ru, W, TaN, TiN, or combinations thereof as some nonlimiting illustrative examples, and may also include a bottom electrode 26 (though in some embodiments it is contemplated for the bottom electrode 26 to be integral with the bottom electrode via (BEVA) 30 to be described). The MRAMs 10 may include other features, such as an illustrative spacer layer 32 of silicon nitride or another suitable dielectric material, and/or an etch stop layer 34 of AlO, AlN, TiN, or so forth. Although not shown, it is contemplated to coat the MRAMs 10 with additional intermetal dielectric (IMD) material and form further metallization layers on top of the MRAMs 10.

With continuing reference to FIG. 1, the structure of the BEVAs 30 is further described. The BEVAs 30 are formed in, and pass through, a dielectric layer 36, which may by way of nonlimiting illustrative example comprise a silicon-rich oxide (SRO) with Si atomic conc >34%, or another dielectric material such as SiO₂, SiC, Si₃N₄, SiOC, or so forth. The BEVAs 30 are formed in via openings which may for example be photolithographically defined and etched through the dielectric layer 36. In the illustrative example, an underlying etch stop layer 38 such as a silicon carbide (SiC) layer is provided to control the etch process. Each BEVA 30 provides electrical connection between the corresponding MRAM 10 and the copper or copper alloy layer 20.

With continuing reference to FIG. 1 and with particular reference now to a detail cross-section 40, each BEVA 30 comprises an electrical via assembly that includes: a metal via 50 which in the illustrative example is a tungsten (W) via; an oxophilic layer 52 disposed around the tungsten or other metal via 50, where the illustrative oxophilic layer 52 includes a titanium nitride (TiN) layer and a titanium (Ti) layer (i.e., a TiN/Ti bi-layer); and a copper-barrier layer 54 disposed around the oxophilic layer 52, where the illustrative copper-barrier layer 54 includes a tantalum (Ta) layer and a tantalum nitride (TaN) layer (i.e., a TaN/Ta bi-layer). Notably, there is no oxide layer at an interface 56 between the copper-barrier layer 54 and the oxophilic layer 52. As recognized herein, materials suitable for use in the copper-barrier layer 54 such as a tantalum layer, a tantalum nitride layer, a molybdenum layer, a molybdenum nitride layer, a cobalt layer, a cobalt nitride layer, or a combination of two or more thereof are susceptible to oxidation when exposed to air. The resulting oxide layer is highly electrically resistive and consequently substantially increases the BEVA contact resistance R_{c,BEVA} thereby reducing the TMR of the MRAM 10 and making it more difficult to distinguish between the high resistance versus low resistance states during readout of the stored state of the MRAM 10. Various fabrication process embodiments described herein provide a mechanism to ensure that no oxide layer is present at the interface 56, thereby advantageously reducing the BEVA contact resistance R_{c,BEVA} and advantageously increasing TMR for the MRAMs 10 and advantageously increasing the read window of the MRAMs 10.

The illustrative embodiment of FIG. 1 employs each BEVA 30 to provide electrical connection between the corresponding MRAM 10 and the copper or copper alloy layer 20. More generally, however, each BEVA 30 can provide electrical connection between an electronic device 10 and the copper or copper alloy layer 20. That is, the electronic device 10 can be an MRAM 10 as in the illustrative example, but alternatively the electronic device 10 could be another type of nonvolatile memory device, or could be another type of electronic device such as a capacitor or so forth.

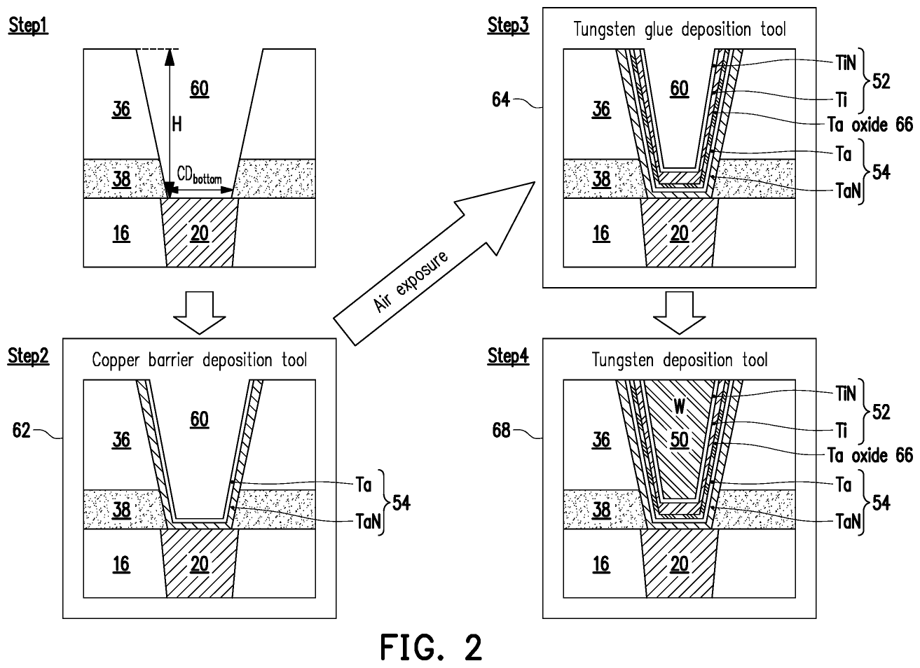

With reference now to FIG. 2, a fabrication process is diagrammatically shown for fabricating a reference bottom electrode via (BEVA) for connecting with an MRAM or other device. The illustrated steps of the fabrication process are identified as “Step 1”, “Step 2”, “Step 3”, and “Step 4” which are performed in that sequence. Prior to Step 1, the semiconductor wafer 8 (see FIG. 1) is provided, including the dielectric layer 36 disposed over the copper or copper alloy layer 20. In Step 1, a via opening 60 is formed in the dielectric layer 36 which exposes a portion of the copper or copper alloy layer 20. The via opening 60 may for example be photolithographically defined and etched through the dielectric layer 36. The via opening 60 has a height H and a bottom CD denoted as CD_{bottom} which is the largest dimension of the via opening 60 at its intersection with the copper or copper alloy layer 20 (or, viewed another way, the dimension CD_{bottom} is the largest dimension of the exposed portion of the copper or copper alloy layer 20). In some embodiments, the formed via opening 60 has a maximum lateral dimension at its intersection with the copper or copper alloy layer of 50 nm or less (that is, CD_{bottom}≤50 nm) and a ratio of via opening height H to maximum lateral dimension CD_{bottom} at its intersection with the copper or copper alloy layer ratio of 1.6 or larger (that is, the ratio H/CD_{bottom}≥1.6). In Step 2, the copper-barrier layer 54 is disposed in the via opening 60. In the illustrative example of FIG. 2 this comprises TaN disposed in the via opening 60 followed by a layer of Ta disposed on the TaN, so that the disposed copper-barrier layer 54 is a TaN/Ta bi-layer. Notably, Step 2 is performed in a diagrammatically indicated copper-barrier deposition tool 62, which may for example be a physical vapor deposition (PVD) chamber, and the TaN may be deposited by atomic layer deposition with a thickness of about 1 nm followed by the Ta deposition by PVD to a thickness of about 7 nm, as one nonlimiting illustrative example.

Following deposition of the copper-barrier layer 54, in the fabrication process of FIG. 2 the semiconductor wafer is removed from the copper-barrier deposition tool 62 and transported to a different diagrammatically indicated tungsten glue deposition tool 64, which is then used in Step 3 to dispose a tungsten glue layer on the copper-barrier layer 54. The transport of the semiconductor wafer from the copper-barrier deposition tool 62 to the tungsten glue deposition tool 64 results in the semiconductor wafer (and more particularly the exposed surface of the copper-barrier layer 54) being exposed to air. This results in formation of a tantalum oxide (Ta oxide) layer 66 on the copper-barrier layer 54 prior to subsequent deposition of the tungsten glue layer 52 (which in the illustrative example comprises oxophilic layers including a bilayer consisting of an oxophilic Ti layer followed by an oxophilic TiN layer). As diagrammatically shown in Step 3 of FIG. 2, the highly electrically resistive Ta oxide layer 66 is thus interposed between the copper-barrier layer 54 and the tungsten glue/oxophilic layer 52. The tungsten glue deposition tool 64 may be a PVD chamber or a chemical vapor deposition (CVD) chamber or a combined PVD/CVD chamber, and the Step 3 in one nonlimiting illustrative embodiment deposits a bilayer including a PVD-deposited Ti layer with a thickness of about 10 nm followed by a CVD-deposited TiN layer with a thickness of about 6 nm. In a Step 4, a tungsten deposition tool 68 is used to fill the via opening 60 with tungsten (W) 50. The tungsten deposition tool 68 could be the same as the tungsten glue deposition tool 64, or could be a different tool. In the latter case, there may be a second air break (not shown in FIG. 2) during transfer of the semiconductor wafer from the tungsten glue deposition tool 64 to the tungsten deposition tool 68. In some embodiments, the tungsten deposition to fill the via opening 60 (Step 4 of FIG. 2) may overfill the via opening 60 so that additional tungsten material is deposited on the surface of the dielectric layer 36. In such embodiments, a further chemical mechanical polishing (CMP) step (not shown in FIG. 2) may be performed to remove this excess tungsten and planarize the surface including the top surface of the tungsten via 50 and the top surface of the dielectric layer 36.

In the following, embodiments are described which enable fabrication of the BEVA 30 as shown in FIG. 1, that is, without the high resistance Ta oxide layer 66 that is introduced by oxidation of the copper-barrier layer 54 during the air break resulting from transfer of the semiconductor wafer from the copper-barrier deposition tool 62 to the tungsten glue deposition tool 64.

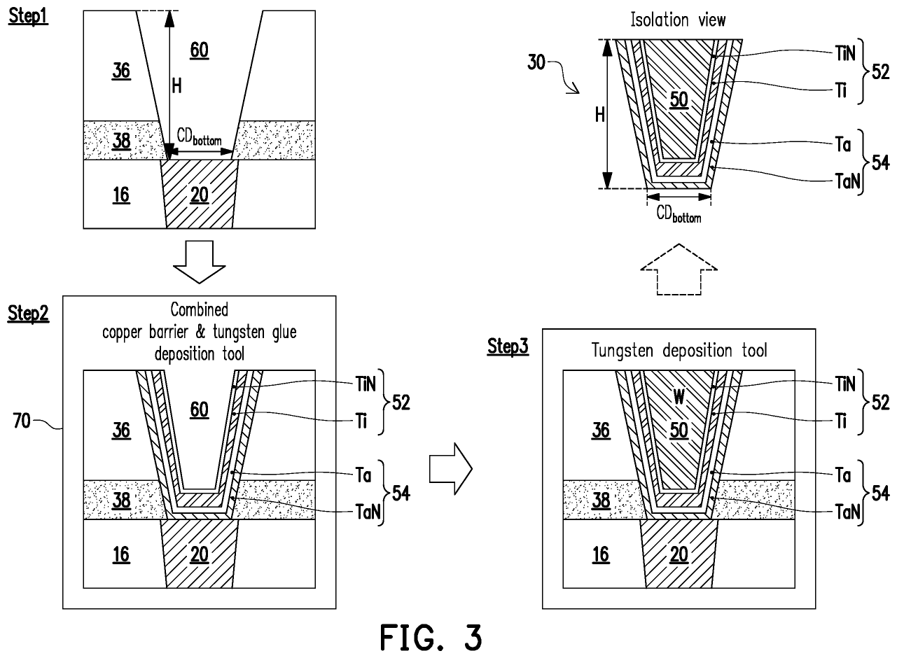

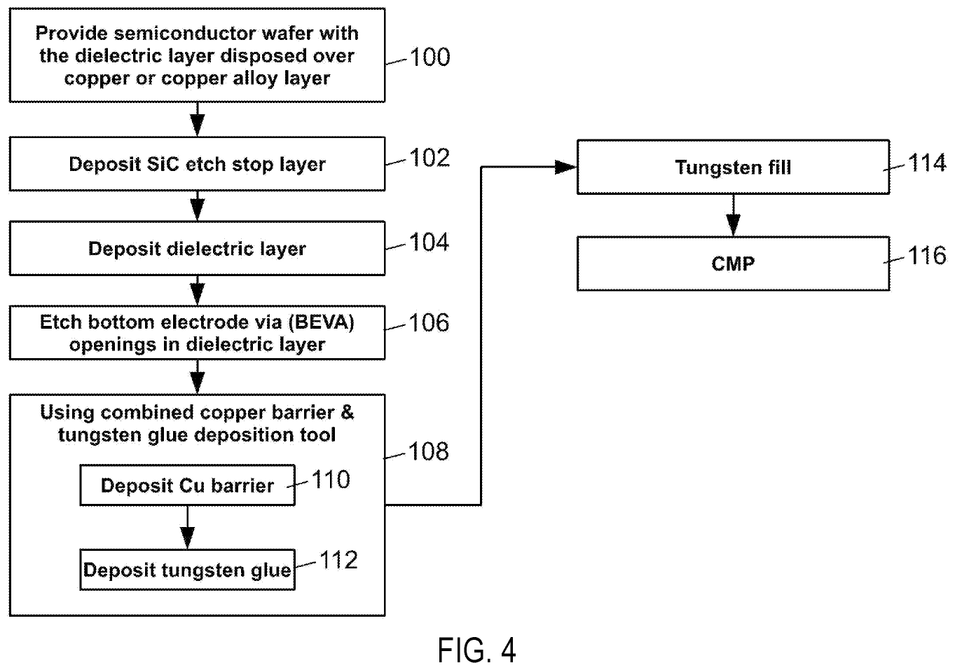

With reference now to FIGS. 3 and 4, a first fabrication process is diagrammatically shown for fabricating a BEVA for connecting with an MRAM or other device. FIG. 3 shows illustrated steps of the fabrication process identified as “Step 1”, “Step 2”, and “Step 3, which are performed in that sequence. Additionally, FIG. 3 shows an “Isolation view” of the final BEVA via assembly 30. FIG. 4 shows a flowchart of the first fabrication process. With initial reference to FIG. 4, in an initial operation 100 the semiconductor wafer 8 (see FIG. 1) is provided, including providing the semiconductor wafer 8 with the dielectric layer 16 disposed over the copper or copper alloy layer 20. In an operation 102, the silicon carbide (SiC) etch stop layer 38 is deposited, followed by deposition of the dielectric layer 36 in an operation 104. The operation 104 may deposit the dielectric layer 36 as a silicon-rich oxide (SRO) with Si atomic conc >34%, or as another dielectric material such as SiO₂, SiC, Si₃N₄, SiOC, or so forth. This is followed by etching of the via opening 60 to expose a portion of the copper or copper alloy layer 20 in operation 106, which results in the structure shown as Step 1 in FIG. 3. This is suitably done as previously described for the fabrication process of FIG. 2. The via opening 60 has a height H and a bottom CD denoted as CD_{bottom} which is the largest dimension of the via opening 60 at its intersection with the copper or copper alloy layer 20 (or, viewed another way, the dimension CD_{bottom} is the largest dimension of the exposed portion of the copper or copper alloy layer 20). In some embodiments, the formed via opening 60 has a maximum lateral dimension at its intersection with the copper or copper alloy layer of 50 nm or less (that is, CD_{bottom}≤50 nm) and a ratio of via opening height H to maximum lateral dimension CD_{bottom} at its intersection with the copper or copper alloy layer ratio of 1.6 or larger (that is, the ratio H/CD_{bottom}≥1.6).

With continuing reference to FIGS. 3 and 4, in an operation 108 indicated in FIG. 4 a combined copper-barrier and tungsten glue deposition tool 70 (see FIG. 3) is used to perform the operations of depositing the copper-barrier 54 (operation 110 of FIG. 4) and depositing the tungsten glue 52 (operation 112 of FIG. 4). The operation 110 may, for example, include disposing the copper-barrier 54 as a tantalum layer, a tantalum nitride layer, a molybdenum layer, a molybdenum nitride layer, a cobalt layer, a cobalt nitride layer, or a combination of two or more thereof. In the illustrative example of FIG. 3 Step 2, the copper-barrier 54 is a bilayer including a tantalum nitride (TaN) layer followed by a tantalum (Ta) layer. In one nonlimiting illustrative embodiment, the TaN layer has a thickness of about 1 nm and the Ta layer has a thickness of about 7 nm. The operation 112 deposits the tungsten glue 52 as an oxophilic layer such as a titanium layer, a titanium nitride layer, or a combination thereof. In the illustrative example shown in FIG. 3 Step 2, the tungsten glue/oxophilic layer 52 is a bilayer including a titanium (Ti) layer followed by a titanium nitride (TiN) layer. In one nonlimiting illustrative embodiment, the Ti layer has a thickness of about 10 nm and the TiN layer has a thickness of about 6 nm. In another nonlimiting illustrative example, the tungsten glue/oxophilic layer 52 is a single TiN layer of about 6 nm thickness.

Notably, because the operations 110 and 112 are performed in the combined copper-barrier and tungsten glue deposition tool 70, there is no air break between the operation 110 and the operation 112. Put another way, the semiconductor wafer 8 is not exposed to air between the end of the disposing 110 of the copper-barrier layer 54 and the start of the disposing 112 of the oxophilic layer 52. Consequently, there is no tantalum oxide (Ta oxide) formed between the copper-barrier layer 54 and the tungsten glue/oxophilic layer 52, and copper-barrier layer 54 directly contacts the oxophilic layer 52. (By comparison, the fabrication process of FIG. 2 has the air break in between these steps resulting in formation of the Ta oxide layer 66 interposed between the copper-barrier layer and the oxophilic layer). The combined copper-barrier and tungsten glue deposition tool 70 may be a single deposition chamber (e.g., a CVD chamber, a PVD chamber, or a combined PVD/CVD chamber) that is configured to perform both operations 110 and 112. In another embodiment, the combined copper-barrier and tungsten glue deposition tool 70 comprises two deposition chambers, one for performing the copper-barrier deposition 110 and the other for performing the tungsten glue/oxophilic layer deposition 112, with the two chambers connected by a vacuum tube with an automated (e.g. robotic) or manually operated wafer transfer system that keeps the wafer under vacuum during transfer from the chamber for performing the operation 110 to the chamber performing the operation 112. Consequently, the semiconductor wafer 8 is not exposed to air between the end of the operation 110 of disposing of the copper-barrier layer 54 and the end of the operation 112 of disposing of the oxophilic layer 52. (Indeed, in this approach the semiconductor wafer 8 is not exposed to air between the beginning of the operation 110 of disposing of the copper-barrier layer 54 and the end of the operation 112 of disposing of the oxophilic layer 52).

With continuing reference to FIGS. 3 and 4, in an operation 114 shown in FIG. 4 the via opening 60 is filled with tungsten to form the tungsten via 50, as shown in Step 3 of FIG. 3. This produces the final BEVA 30, which is shown in isolation in the Isolation view of FIG. 3. The operation 114 may be performed in the same combined copper-barrier and tungsten glue deposition tool 70 used to perform the operations 110 and 112, in which case the semiconductor wafer 8 is not exposed to air between the end of the operation 110 of disposing the copper-barrier layer 54 and the end of the operation 114 of filling of the via opening 60 with tungsten. Again, this ensure that the copper-barrier layer 54 is not exposed to oxygen during an air break, and so there is no Ta oxide formed on the copper-barrier layer 54 so as to be interposed between the copper-barrier layer 54 and the oxophilic layer 52.

In other embodiments, the operation 114 may be performed in a different chamber, so that the semiconductor wafer is exposed to an air break between the operation 112 of disposing the oxophilic layer 52 and the filling of the tungsten. However, in this case there is still expected to be no Ta oxide formation on the copper-barrier layer 54 because the oxophilic layer 52 provides protection against oxygen ingress from the air to the copper-barrier layer 54 during the air break.

In some embodiments, the operation 114 may overfill the via opening 60 so that additional tungsten material is deposited on the surface of the dielectric layer 36. In such embodiments, a further chemical mechanical polishing (CMP) step 116 indicated in FIG. 4 may be performed to remove this excess tungsten and planarize the surface including the top surface of the tungsten via 50 and the top surface of the dielectric layer 36. The final BEVA 30 shown in the Isolation View of FIG. 3 has height H which is the same as the height H of the via opening 60 (neglecting any reduction due to the CMP 116), and has a bottom CD (denoted as CD_{bottom}) which is the maximum lateral dimension at its contact with the copper or copper alloy layer 20, and is the same as the bottom CD_{bottom} of the via opening 60. In some embodiments, the electrical via assembly (i.e. BEVA) 60 has its maximum lateral dimension CD_{bottom} at its contact with the copper or copper alloy layer 20 of 50 nm or less, and a ratio of via assembly height H to that maximum lateral dimension CD_{bottom} of 1.6 or larger. As noted previously, these dimensions have advantages when the BEVA 30 is used to connect with the bottom electrode 26 of an MRAM 10 (see FIG. 1) in that it facilitates a compact MRAM design with comparably small critical dimension for the magnetic tunnel junction (MTJ) of the MRAM 10, which results in less power consumption and faster write time for the MRAM 10.

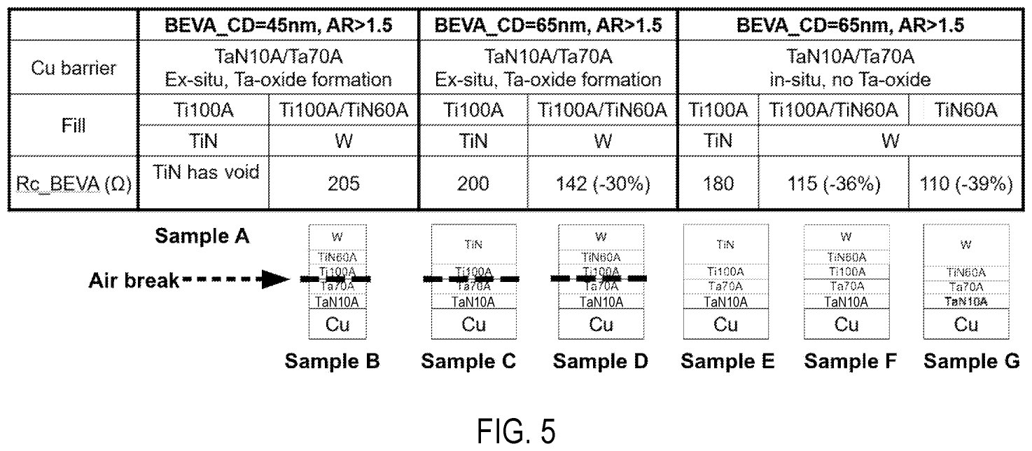

With reference now to FIG. 5, some nonlimiting illustrative experimental results are presented for seven test BEVA samples identified in FIG. 5 as Sample A, Sample B, Sample C, Sample D, Sample E, Sample F, and Sample G. BEVA samples A and B had CD_{bottom} of about 45 nm while samples C, D, E, F, and G had CD_{bottom} of about 65 nm. (Note that FIG. 5 uses the notation BEVA_CD for CD_{bottom}). All samples A-G had aspect ratio AR corresponding to the ratio H/CD_{bottom} of greater than about 1.5. Samples A, C, and E used TiN (with an initial Ti thickness of about 10 nm) as the via material, while samples B, D, F, and G used tungsten (W, with tungsten glue as indicated in FIG. 5) as the via material. Samples A, B, C, and D had an air break between the deposition of the copper-barrier (which was about 1 nm TaN/about 7 nm Ta in the samples) and the subsequent layers, while samples E, F, and G had no air break during deposition of the BEVA structure. The samples A, B, C, and D that had the air break are also referred to as “Ex situ” in FIG. 5 with the further indication that the air break is expected to lead to “Ta-oxide formation”, while the samples E, F, and G with no air break are also referred to as “In situ” in FIG. 5 with the further indication that the lack of the air break is expected to lead to “no Ta-oxide”. The structures are indicated by diagrammatic cross-sectional views in the lower portion of FIG. 5, with the upper table tabulating the Cu barrier structure and the fill material. The table also lists the measured Rc_BEVA resistance (in ohms, i.e. Ω).

As summarized in FIG. 5, sample A with CD_{bottom} of about 45 nm and TiN filler has poor property, as the TiN had a central void (i.e., the TiN failed to completely fill the via opening 60). By contrast, sample B with CD_{bottom} of about 45 nm and tungsten filler provided complete filling of the via opening 60 with the tungsten, but had a high Rc_BEVA resistance of about 205 ohms which is believed to be due to the formation of highly resistive Ta oxide on the tantalum-based copper-barrier during the air break. (A similar oxidation is expected to occur if the copper-barrier is molybdenum-based or cobalt-based as these materials are also prone to oxidation during air exposure, although these were not tested).

Samples C and D employed a larger CD_{bottom} of about 65 nm, with TiN filler for sample C and tungsten filler for sample D. TiN filler sample C exhibited higher resistance (about 200 ohm) than tungsten filler sample D (about 142 ohm), corresponding to about 30% lower resistance for tungsten sample D when compared with TiN sample C. While this is an improvement, it is less of an improvement than might be expected given the much lower resistivity of tungsten (<30 μΩ·cm) compared with TiN (>300 μΩ·cm). This is believed to be due at least in part to the formation of high resistance Ta oxide on the copper-barrier during the air break.

Samples E, F, and G also had CD_{bottom} of about 65 nm, but were fabricated with no air break, and hence are expected to have no Ta oxide layer formed between the copper-barrier and the subsequent layers. Sample E employed TiN filler and had a measured resistance Rc_BEVA of about 180 ohms. Sample F employed tungsten filler and a tungsten glue/oxophilic bilayer of about 10 nm Ti/about 6 nm TiN. Sample F had a measured resistance Rc_BEVA of about 115 ohms, corresponding to about 36% lower resistance than the comparable TiN sample E. Sample G also employed tungsten filler but had a tungsten glue/oxophilic single layer of about 6 nm TiN, and had a lowest measured resistance Rc_BEVA of about 110 ohms corresponding to about 39% lower resistance than the comparable TiN sample E. Notably, both tungsten fill samples F and G which were formed without an air break had substantially lower resistance Rc_BEVA than the tungsten fill sample D of the same critical dimension but fabricated with the air break. Hence, the experimental results of FIG. 5 demonstrate reduced BEVA resistance is achieved by omission of the air break after the deposition of the copper-barrier layer 54. It is to be appreciated that these experimental samples are illustrative, and that the results in a given experiment can be expected to depend on various factors in structure formation and measurement.

In the experimental samples E, F, and G with no air break, the entire structure including formation of the entire tungsten glue layer 52 (operation 112 of FIG. 4) and the subsequent tungsten fill (operation 114 of FIG. 4) are performed without an air break. Referring back to FIG. 2, a significant source of higher BEVA resistance is believed to be formation of the Ta oxide 66 on the copper-barrier 54 during the air break between Step 2 and Step 3 of the fabrication process of FIG. 2. This is experimentally supported by comparing sample D of FIG. 5 with sample F of FIG. 5, where the two samples D and F have the same structure and differ by the air break after the copper-barrier deposition in sample D versus no such air break in the fabrication of sample F in some embodiments.

Based on the foregoing observation, although not experimentally tested it is expected that similar improvement (i.e. reduction) in BEVA resistance can be achieved by a variant fabrication process previously described with reference to FIG. 3, in which there is an air break between FIG. 3 Step 2 (combined copper-barrier deposition 110 and oxophilic layer deposition 112) and Step 3 (tungsten fill 114 performed in a different deposition chamber). In this variant fabrication process, the oxophilic layer 52 is expected to provide protection against oxygen ingress from the air to the copper-barrier layer 54 during the air break.

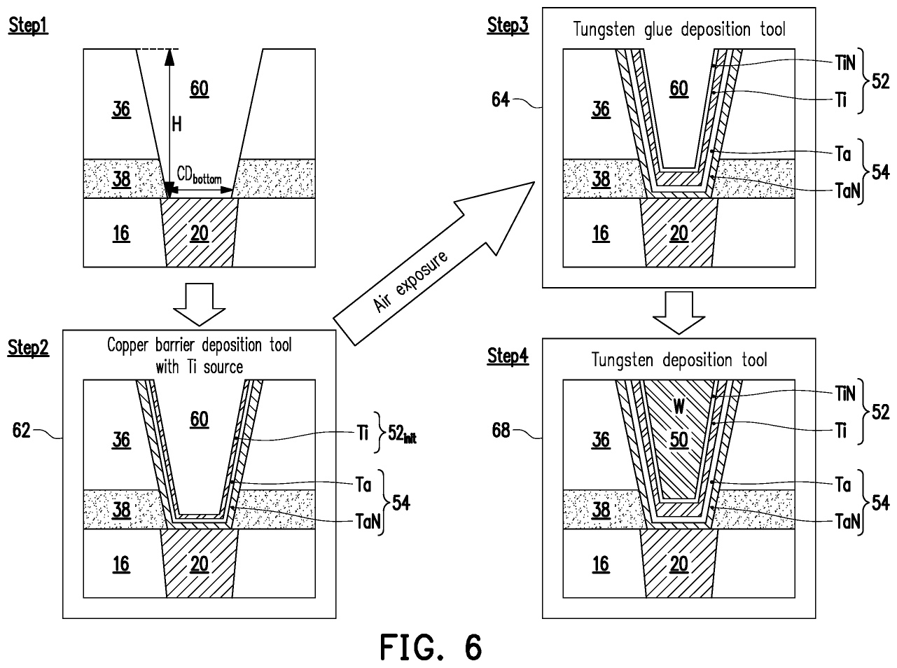

With reference now to FIG. 6, another variant fabrication process is shown, also based on the foregoing observation. This process employs the same Step 1 to form the via opening 60. However, FIG. 6 Step 2 entails the operation 110 of depositing the copper-barrier 54 followed by deposition of only an initial oxophilic layer 52ᵢₙᵢₜ, which in the illustrative example of FIG. 6 is an initial titanium (Ti) layer in some embodiments. (Alternatively, an initial TiN layer is contemplated). Advantageously, the Step 2 of FIG. 6 can be performed with the same copper-barrier deposition tool 62 used in the fabrication process of FIG. 2, modified only to provide a titanium source (e.g. brief flow of a titanium gas precursor using a CVD chamber 62, or for example an additional Ti target in the case of a PVD chamber 62) in some embodiments. In the variant fabrication process of FIG. 6 the semiconductor wafer 8 is not exposed to air between the end of the disposing of the copper-barrier layer 54 and the start of the disposing of the oxophilic layer 52 (i.e., in this variant process the start of the disposing of the initial oxophilic layer 52ᵢₙᵢₜ). Advantageously, the initial oxophilic layer 52ᵢₙᵢₜ is expected to provide sufficient protection for the copper-barrier 54 during a subsequent air break during which the semiconductor wafer is transferred to the tungsten glue deposition tool 64 (which can again be the same as that used in the fabrication process of FIG. 2) to complete deposition of the tungsten glue/oxophilic layer 52, as shown in Step 3 of FIG. 6. Tungsten fill Step 4 of FIG. 6 then corresponds identically to tungsten fill Step 4 of the fabrication process of FIG. 2. Hence, in the embodiment of FIG. 6 the initial oxophilic layer 52ᵢₙᵢₜ is disposed on the copper-barrier layer 54, where the semiconductor wafer 8 is not exposed to air between the end of the disposing of the copper-barrier layer 54 and an end of the disposing of the initial oxophilic layer 52ᵢₙᵢₜ. Thereafter, the semiconductor wafer 8 is exposed to air after the end of disposing of the initial oxophilic layer 52ᵢₙᵢₜ, and after the exposure to air, at least one additional oxophilic layer is disposed on the initial oxophilic layer 52ᵢₙᵢₜ to complete the deposition of the tungsten glue/oxophilic layer 52.

Review of the fabrication process of FIGS. 3 and 4 and the variant fabrication process of FIG. 6 demonstrates that in each such fabrication process the semiconductor wafer 8 is advantageously not exposed to air during a time interval encompassing the deposition 110 of the copper-barrier layer 54 and the deposition of at least an initial portion of the oxophilic layer 52. Hence, there is no tantalum oxide layer 66 between the copper-barrier layer 54 and the oxophilic layer 52 in the final BEVA 30.

In the following, some further embodiments are described.

In a nonlimiting illustrative embodiment, an integrated circuit fabrication method comprises: providing a semiconductor wafer including a dielectric layer disposed over a copper or copper alloy layer; forming a via opening in the dielectric layer exposing a portion of the copper or copper alloy layer; disposing a copper-barrier layer in the via opening; disposing an oxophilic layer on the copper-barrier layer; after disposing the oxophilic layer, filling the via opening with tungsten to form a tungsten via; and forming an electronic device in electrical contact with the copper or copper alloy layer by way of the tungsten via. The deposition of the copper-barrier layer and the deposition of at least an initial portion of the oxophilic layer are performed in a same deposition chamber.

In a nonlimiting illustrative embodiment, an integrated circuit fabrication method comprises: providing a semiconductor wafer including a dielectric layer disposed over a copper or copper alloy layer; forming a via opening in the dielectric layer exposing a portion of the copper or copper alloy layer; disposing a copper-barrier layer in the via opening wherein the copper-barrier layer includes a tantalum layer, a tantalum nitride layer, a molybdenum layer, a molybdenum nitride layer, a cobalt layer, a cobalt nitride layer, or a combination of two or more thereof; disposing an oxophilic layer including a titanium nitride layer, a titanium layer, or a combination thereof on the copper-barrier layer wherein the semiconductor wafer is not exposed to air during a time interval encompassing the deposition of the copper-barrier layer and the deposition of at least an initial portion of the oxophilic layer; after disposing the oxophilic layer, filling the via opening with a metal to form a metal via; and forming an electronic device in electrical contact with the copper or copper alloy layer by way of the metal via.

In a nonlimiting illustrative embodiment, an integrated circuit device comprises: an electronic device; a copper or copper alloy layer; and an electrical via assembly providing electrical connection between the electronic device and the copper or copper alloy layer. The electrical via assembly includes: a tungsten via; an oxophilic layer disposed around the tungsten via; and a copper-barrier layer disposed around the oxophilic layer. The oxophilic layer includes a titanium nitride layer, a titanium layer, or a combination thereof. The copper-barrier layer includes a tantalum layer, a tantalum nitride layer, or a combination thereof. The copper-barrier layer directly contacts the oxophilic layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit fabrication method comprising:
providing a semiconductor wafer including a dielectric layer disposed over a copper or copper alloy layer;
forming a via opening in the dielectric layer exposing a portion of the copper or copper alloy layer;
disposing a copper-barrier layer in the via opening;
disposing an oxophilic layer on the copper-barrier layer;
after disposing the oxophilic layer, filling the via opening with tungsten to form a tungsten via; and
forming an electronic device in electrical contact with the copper or copper alloy layer by way of the tungsten via;
wherein the deposition of the copper-barrier layer and the deposition of at least an initial portion of the oxophilic layer are performed in a same deposition chamber.

2. The method of claim 1 wherein:
the disposing of the copper-barrier layer in the via opening includes disposing a tantalum layer, a tantalum nitride layer, a molybdenum layer, a molybdenum nitride layer, a cobalt layer, a cobalt nitride layer, or a combination of two or more thereof; and
the disposing of the oxophilic layer includes disposing a titanium layer, a titanium nitride layer, or a combination thereof.

3. The method of claim 1 wherein the semiconductor wafer is not exposed to air between the end of the disposing of the copper-barrier layer and an end of the disposing of the oxophilic layer.

4. The method of claim 3 wherein the disposing of the oxophilic layer on the copper-barrier layer includes:
disposing a titanium layer on the copper-barrier layer; and
disposing a titanium nitride layer on the titanium layer.

5. The method of claim 3 wherein the semiconductor wafer is not exposed to air between the end of the disposing of the copper-barrier layer and an end of the filling of the via opening with tungsten.

6. The method of claim 1 wherein the disposing of the oxophilic layer on the copper-barrier layer includes:
disposing an initial oxophilic layer on the copper-barrier layer in the same deposition chamber used in disposing the copper-barrier layer;
exposing the semiconductor wafer to air after the end of disposing of the initial oxophilic layer; and
after exposing the semiconductor wafer to air, disposing at least one additional oxophilic layer on the initial oxophilic layer.

7. The method of claim 6 wherein:
the initial oxophilic layer is a titanium layer or a titanium nitride layer; and
the at least one additional oxophilic layer includes a titanium layer, a titanium nitride layer, or a combination thereof.

8. The method of claim 1 further comprising:
after the filling of the via opening with tungsten to form the tungsten via, performing chemical mechanical polishing (CMP) planarize a surface including a top surface of the tungsten via and a top surface of the dielectric layer.

9. The method of claim 1 wherein the electronic device is a nonvolatile memory device.

10. The method of claim 9 wherein the nonvolatile memory device is a magnetoresistive random access memory (MRAM).

11. The method of claim 1 wherein the formed via opening has a maximum lateral dimension at its intersection with the copper or copper alloy layer of 50 nm or less and a ratio of via opening height to maximum lateral dimension at its intersection with the copper or copper alloy layer of 1.6 or larger.

12. An integrated circuit fabrication method comprising:
providing a semiconductor wafer including a dielectric layer disposed over a copper or copper alloy layer;
forming a via opening in the dielectric layer exposing a portion of the copper or copper alloy layer;
disposing a copper-barrier layer in the via opening wherein the copper-barrier layer includes a tantalum layer, a tantalum nitride layer, a molybdenum layer, a molybdenum nitride layer, a cobalt layer, a cobalt nitride layer, or a combination of two or more thereof;
disposing an oxophilic layer including a titanium nitride layer, a titanium layer, or a combination thereof on the copper-barrier layer wherein the semiconductor wafer is not exposed to air during a time interval encompassing the deposition of the copper-barrier layer and the deposition of at least an initial portion of the oxophilic layer;
after disposing the oxophilic layer, filling the via opening with a metal to form a metal via; and
forming an electronic device in electrical contact with the copper or copper alloy layer by way of the metal via.

13. The method of claim 12 wherein the filling the via opening with a metal comprises filling the via opening with tungsten to form the metal via as a tungsten via.

14. The method of claim 12 wherein the semiconductor wafer is not exposed to air during a time interval encompassing the deposition of the copper-barrier layer and the deposition of entire the oxophilic layer.

15. The method of claim 12 wherein the semiconductor wafer is not exposed to air a time interval encompassing the deposition of the copper-barrier layer and the deposition of the oxophilic layer and the filling of the via opening with the metal to form the metal via.

16. The method of claim 12 wherein the disposing of the oxophilic layer on the copper-barrier layer includes:
disposing the initial oxophilic layer on the copper-barrier layer;
after disposing the initial oxophilic layer, exposing the semiconductor wafer to air; and
after exposing the semiconductor wafer to air, completing the disposing of the oxophilic layer.

17. The method of claim 12 wherein the electronic device is a magnetoresistive random access memory (MRAM) and the via opening has a maximum lateral dimension of 65 nm and a vertical/lateral aspect ratio of 1.6 or larger.

18. An integrated circuit device comprising:
an electronic device;
a copper or copper alloy layer; and
an electrical via assembly providing electrical connection between the electronic device and the copper or copper alloy layer;
wherein the electrical via assembly includes:
a tungsten via;
an oxophilic layer disposed around the tungsten via, the oxophilic layer including a titanium nitride layer, a titanium layer, or a combination thereof; and
a copper-barrier layer disposed around the oxophilic layer, the copper-barrier layer including a tantalum layer, a tantalum nitride layer, or a combination thereof;
wherein the copper-barrier layer directly contacts the oxophilic layer.

19. The integrated circuit device of claim 18 wherein the electronic device is a magnetoresistive random access memory (MRAM).

20. The integrated circuit device of claim 19 wherein the electrical via assembly has a maximum lateral dimension at its contact with the copper or copper alloy layer of 50 nm or less and a ratio of via assembly height to maximum lateral dimension at its contact with the copper or copper alloy layer of 1.6 or larger.
